(19) United States
(12) Patent Application Publication
(10) Pub. No.: US 2026/0310086 A1
(43) Pub. Date: Oct. 8, 2026

(54) MAGNETIC ANNEALING OF METAL OXIDE BASED RESISTS

(71) Applicant: Applied Materials, Inc., Santa Clara, CA (US)

(72) Inventor: NASRIN KAZEM, Santa Clara, CA (US)

(21) Appl. No.: 19/556,753

(22) Filed: Mar. 4, 2026

Related U.S. Application Data
(60) Provisional application No. 63/782,532, filed on Apr. 2, 2025.

(51) Int. Cl. G03F 7/38; G03F 7/004; G03F 7/20

(52) U.S. Cl. CPC G03F 7/38; G03F 7/0043; G03F 7/2004; G03F 7/201

(57) ABSTRACT

Embodiments described herein relate to a method for developing a resist layer that has been exposed to form an exposed region with metal radicals. In an embodiment, the method may include applying a magnetic field to the resist layer, where the magnetic field aligns the metal radicals within the exposed region into substantially vertical lines. In an embodiment, the method may further include implementing a post exposure bake of the resist layer, and removing the exposed region of the resist layer or an unexposed region of the resist layer with a developing process to form a patterning mask.

### CROSS-REFERENCE TO RELATED APPLICATIONS

This application claims the benefit of U.S. Provisional Application No. 63/782,532, filed on Apr. 2, 2025, the entire contents of which are hereby incorporated by reference herein.

### BACKGROUND

### 1) Field

Embodiments relate to the field of semiconductor manufacturing and, in particular, magnetic annealing of metal oxide resists.

### 2) Description of Related Art

Metal-oxide resists (MORs) are commonly used for extreme ultraviolet (EUV) lithography due to their high EUV absorption and photochemical sensitivity. EUV exposure generates metal radicals and other intermediates. These radicals and intermediates may be highly reactive, leading to uncontrolled diffusion and molecular disorder. Diffusion of the radicals is increased during the post exposure bake (PEB) process. Traditional PEB processes rely solely on thermal control to reduce line width roughness (LWR) and/or line edge roughness (LER).

However, the thermal control may not fully address the stochastic distribution of reactive species, including the metal radicals, generated during the EUV exposure and the subsequent crosslinking. Instead, the poorly controlled diffusion driven by existing PEB processes directly contributes to roughness in patterned features. That is, as the radicals diffuse, the interface between exposed regions and unexposed regions of the resist layer become less defined. As such, the developing process may result in a resist layer that has higher LER and/or LWR.

### SUMMARY

Embodiments described herein relate to a method for developing a resist layer that has been exposed to form an exposed region with metal radicals. In an embodiment, the method may include applying a magnetic field to the resist layer, where the magnetic field aligns the metal radicals within the exposed region into substantially vertical lines. In an embodiment, the method may further include implementing a post exposure bake of the resist layer, and removing the exposed region of the resist layer or an unexposed region of the resist layer with a developing process to form a patterning mask.

Embodiments described herein relate to a method for developing a resist layer that includes exposing a region of the resist layer to extreme ultraviolet (EUV) radiation, where the EUV radiation generates metal radicals in an exposed region of the resist layer. In an embodiment, the method may further include exposing the resist layer to a magnetic field, where magnetic field lines of the magnetic field are oriented at an angle between 0° and 90° with respect to a surface of the resist layer, and where the magnetic field aligns the metal radicals within the exposed region. In an embodiment, the method may further include implementing a post exposure bake of the resist layer, and removing the exposed region of the resist layer or an unexposed region of the resist layer with a developing process to form a patterning mask.

Embodiments described herein relate to a method that includes applying a resist layer over a substrate, where the resist layer includes a metal oxide cluster. In an embodiment, the method may further include exposing a region of the resist layer to deep ultraviolet (DUV) and/or extreme ultraviolet (EUV) radiation, where the DUV radiation and/or EUV radiation generates metal radicals from the metal oxide cluster in an exposed region of the resist layer. In an embodiment, the method may further include exposing the resist layer to a magnetic field, and where the magnetic field aligns the metal radicals within the exposed region. In an embodiment, the method may further include implementing a post exposure bake of the resist layer, and removing the exposed region of the resist layer or an unexposed region of the resist layer with a developing process to form a patterning mask.

### BRIEF DESCRIPTION OF THE DRAWINGS

FIG. 1A is a cross-sectional illustration of a substrate with a patterning stack and a resist layer over the patterning stack, in accordance with an embodiment.

FIG. 1B is a cross-sectional illustration of the substrate after a region of the resist layer is exposed, in accordance with an embodiment.

FIG. 1C is a cross-sectional illustration of the substrate after a post exposure bake (PEB) process, in accordance with an embodiment.

FIG. 1D is a cross-sectional illustration of the substrate after the resist layer is developed, in accordance with an embodiment.

FIG. 2A is a schematic illustration of metal oxide clusters of a metal oxide resist (MOR) material, in accordance with an embodiment.

FIG. 2B is a schematic illustration of metal oxide clusters of the MOR material after extreme ultraviolet (EUV) exposure to form metal radicals, in accordance with an embodiment.

FIG. 3A is a cross-sectional illustration of a device with a resist layer during EUV exposure that results in the formation of metal radicals, in accordance with an embodiment.

FIG. 3B is a cross-sectional illustration of a device with a resist layer that is exposed to a magnetic field to align the metal radicals, in accordance with an embodiment.

FIG. 3C is a cross-sectional illustration of the device after the resist layer is baked and removed from the magnetic field, in accordance with an embodiment.

FIG. 3D is a cross-sectional illustration of the device after the resist layer is developed to remove the exposed region of the resist layer, in accordance with an embodiment.

FIG. 3E is a cross-sectional illustration of the device after a pattern in the resist layer is transferred into underlying layers, in accordance with an embodiment.

FIG. 4 is a schematic illustration of a system for applying a magnetic field to a resist layer over a substrate, in accordance with an embodiment.

FIG. 5 is a flow diagram that depicts a process for developing an MOR material on a substrate with EUV exposure and the application of a magnetic field in order to align metal radicals into substantially vertical lines for improved line edge roughness (LER) and/or line width roughness (LWR), in accordance with an embodiment.

FIG. 6 illustrates a block diagram of an exemplary computer system that may be used in conjunction with a processing tool, in accordance with an embodiment.

### DETAILED DESCRIPTION

Embodiments described herein include magnetic annealing of metal oxide resists. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, thermal control during post exposure bake (PEB) processes may not fully address the stochastic distribution of reactive species (which may include metal radicals) that are generated during the extreme ultraviolet (EUV) exposure and the subsequent crosslinking. Accordingly, the poorly controlled diffusion driven by existing PEB processes directly contributes to roughness in patterned features. This results in the resist layer having poor LER and/or LWR.

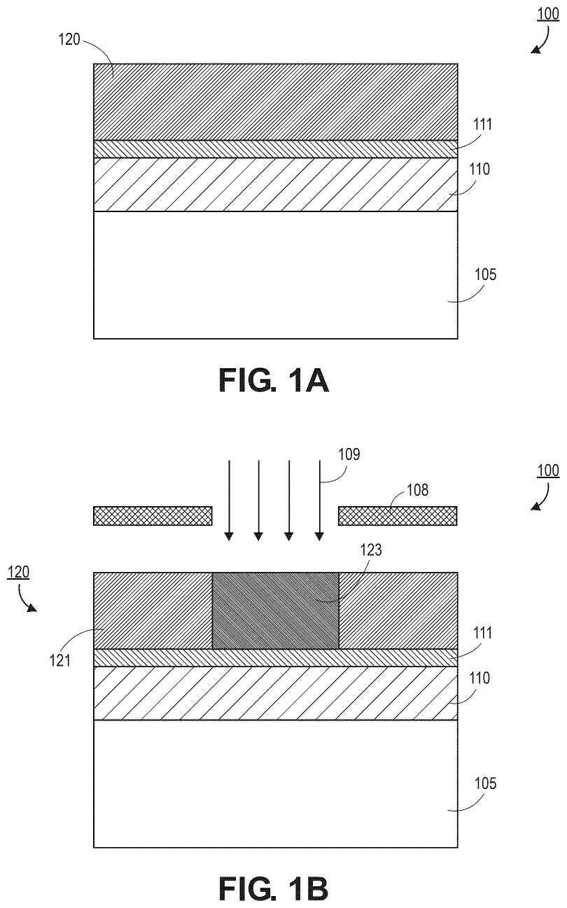

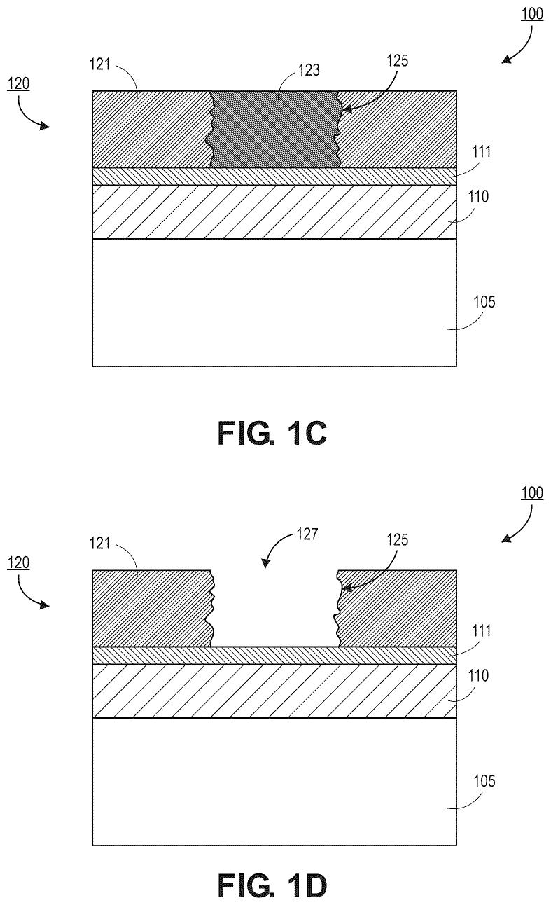

An example, of a EUV and/or deep ultraviolet (DUV) exposure and development process that leads to suboptimal patterning outcomes is shown with respect to FIG. 1A-1D.

Referring now to FIG. 1A, a cross-sectional illustration of a portion of a device 100 is shown, in accordance with an embodiment. In an embodiment, the device 100 may include a patterning stack 110 and a resist layer 120 over the patterning stack 110. The resist layer 120 and the patterning stack 110 may be provided over a substrate 105. In an embodiment, the patterning stack 110 may include one or more layers suitable for transferring a pattern formed into the resist layer 120 into the underlying substrate 105. For example, the patterning stack 110 may comprise multiple layers, such as a silicon hardmask layer, a carbon hardmask layer, an antireflective coating, and/or the like. In some embodiments, the patterning stack 110 may comprise an underlayer 111. In an embodiment, the underlayer 111 may comprise a material that is sensitive to extreme ultraviolet (EUV) radiation or deep ultraviolet (DUV) radiation in order to generate species (e.g., elements, molecules, electrons, etc.) that can diffuse into the overlying resist layer 120 in order to participate in the solubility switch reaction. In an embodiment, the underlayer 111 may be deposited with a dry deposition process (e.g., chemical vapor deposition (CVD), atomic layer deposition (ALD), or the like). Though, in other embodiments the underlayer 111 may be omitted.

In an embodiment, the resist layer 120 may comprise a material that reacts when exposed to EUV and/or DUV radiation in order to generate a solubility switch. In a particular embodiment, the resist layer 120 may comprise an MOR material. The resist material may also include an organometallic oxide material. In an embodiment, an MOR material may comprise a photoresist material with one or more metals (e.g., tin, indium, hafnium, zinc, zirconium, tellurium, or any combination thereof). The MOR material may also comprise an organotin-oxo photoresist material, an organoindium-oxo photoresist material, or the like.

Referring now to FIG. 1B, a cross-sectional illustration of the portion of the device 100 during an exposure of the resist layer 120 is shown, in accordance with an embodiment. A mask 108 or the like may be used to block radiation 109 (e.g., EUV radiation or deep ultraviolet (DUV) radiation). In an embodiment, the selective exposure of the resist layer 120 may result in the formation of an exposed region 123 and an unexposed region 121. In an embodiment, the radiation 109 may result in a chemical reaction within the exposed region 123 that drives the formation of reactive species and/or metal radicals.

Referring now to FIG. 1C, a cross-sectional illustration of the portion of the device 100 after a PEB process is implemented is shown, in accordance with an embodiment. In an embodiment, the PEB process may include the application of thermal energy to the resist layer 120. As such, reactive species and/or metal radicals within the exposed region 123 may diffuse in a relatively uncontrolled manner. Accordingly, the definition of the sidewalls 125 of the exposed region 123 becomes less consistent. That is, the sidewalls 125 may have a non-linear profile.

Referring now to FIG. 1D, a cross-sectional illustration of the portion of the device 100 after the resist layer 120 is developed is shown, in accordance with an embodiment. In an embodiment, the developing process may include an etching process or the like that removes the exposed region 123. As shown, the sidewalls 125 of the opening 127 formed through the resist layer 120 are rough due to the uncontrolled diffusion of the metal radicals and other reactive species. As such, the resist layer 120 may have suboptimal LER and/LWR, which can lead to poor pattern transfer into the underlying layers.

Accordingly, embodiments disclosed herein may include a process that provides better control of the diffusion of metal radicals and/or other reactive species. For example, the metal radicals and other intermediates are responsive to magnetic fields due to their unpaired electrons. Since the metal radicals are magnetic-sensitive, the metal radicals may be aligned under a magnetic field. By applying a magnetic field during post-exposure annealing, the metal radicals may be aligned in a substantially vertical line which minimizes random diffusion. As such, molecular disorder is reduced, and the edges of the exposed region retain a more linear profile after the PEB process. As such the resulting LER and/or LWR of the resist layer after development is improved.

In some embodiments, the application of the magnetic field to the resist layer may be done during the PEB process. Some embodiments may also comprise applying a magnetic field during the exposure process and the PEB process. The magnetic field may be oriented so that the magnetic field lines are substantially orthogonal to a top surface of the resist layer. As such, the metal radicals may align in a substantially linear direction along the magnetic field lines. In an embodiment, the substrate and the resist layer may be rotated through the magnetic field.

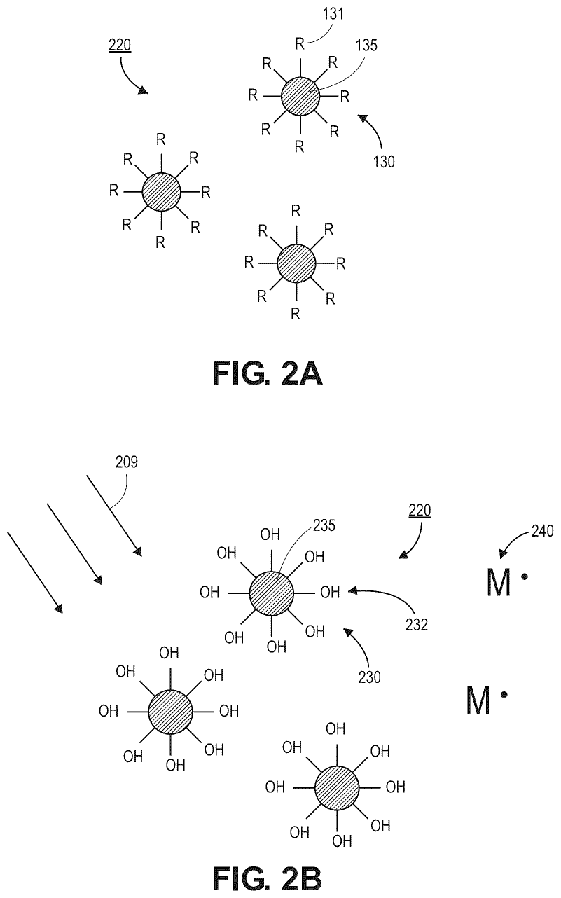

Referring now to FIG. 2A, a schematic illustration of metal cages 230 of an MOR material 220 is shown, in accordance with an embodiment. In an embodiment, the metal cages 230 may comprise a metal-oxide cluster 235. The metal-oxide cluster 235 may comprise one or more metal atoms and one or more oxygen atoms that are bonded together. The individual metal atoms and oxygen atoms are not shown for simplicity in FIG. 2A. In some embodiments, the metal within the metal-oxide clusters 235 may comprise one or more of tin, indium, hafnium, zinc, zirconium, tellurium, or any combination thereof. The MOR material 220 of the metal cages 230 may also comprise an organotin-oxide material, an organoindium-oxide material, or the like. In an embodiment, the metal cages 230 may comprise alkyl terminations 231 (indicated generically as an R group). Any suitable alkyl termination 231 may be used in various embodiments.

Referring now to FIG. 2B, a schematic illustration of metal cages 230 of the MOR material 220 after exposure to EUV and/or DUV radiation 209 is shown, in accordance with an embodiment. As shown, the reaction between the metal cages 230 and the radiation 209 results in bonds between the metal M and the carbon of the alkyl terminations 231 breaking to form metal radicals 240 (represented generically as M·) and hydroxyl (OH) terminations 232. The M may represent any of the metal atoms that are include in the metal cages 230. For example, in some embodiments the metal radicals 240 may be tin radicals. The metal radicals 240 may have unpaired electrons. The unpaired electrons may render the metal radicals 240 responsive to alignment with a magnetic field. Further, while not shown in FIGS. 2A and 2B, other reactive species may be formed as a result of the radiation 209 exposure. In some instances, the additional reactive species (e.g., electrons, clusters, etc.) may also be responsive to magnetic fields.

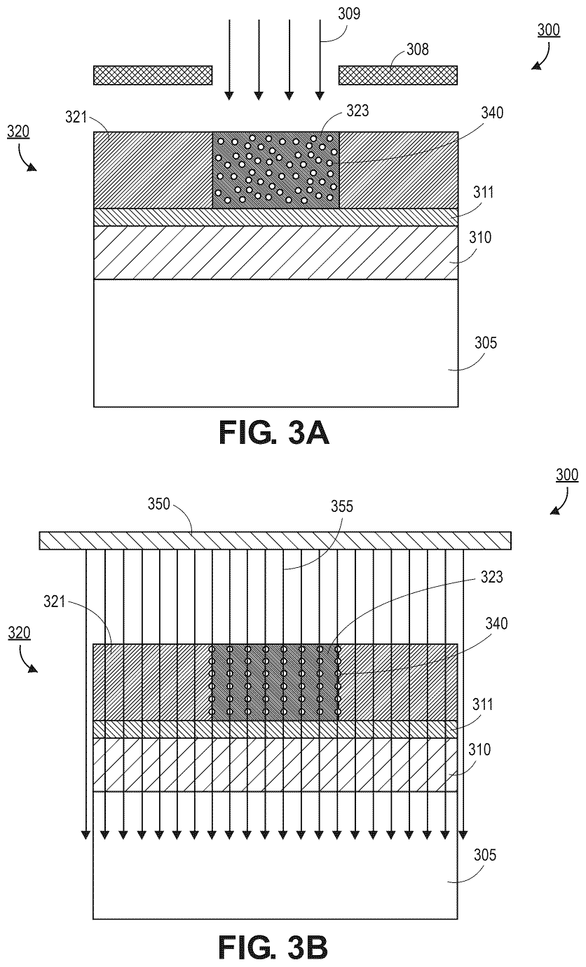

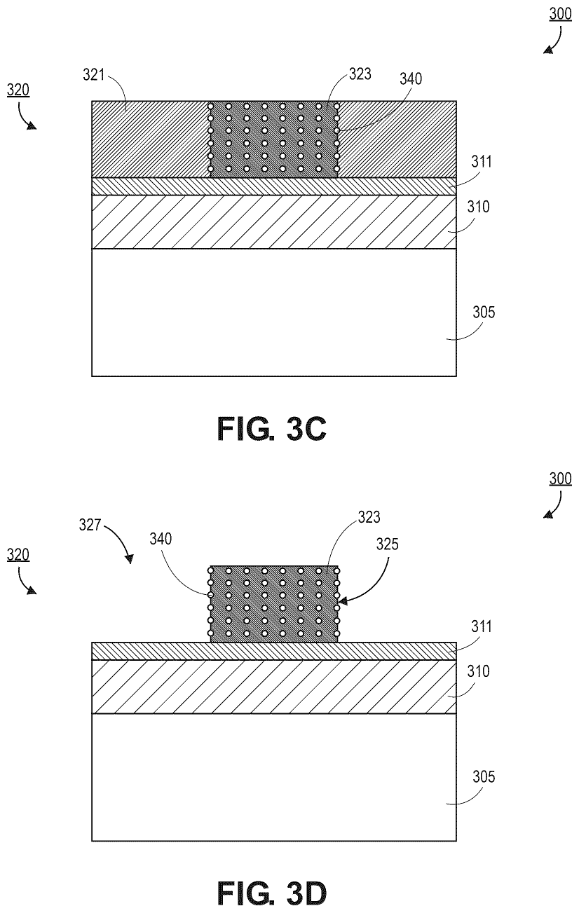

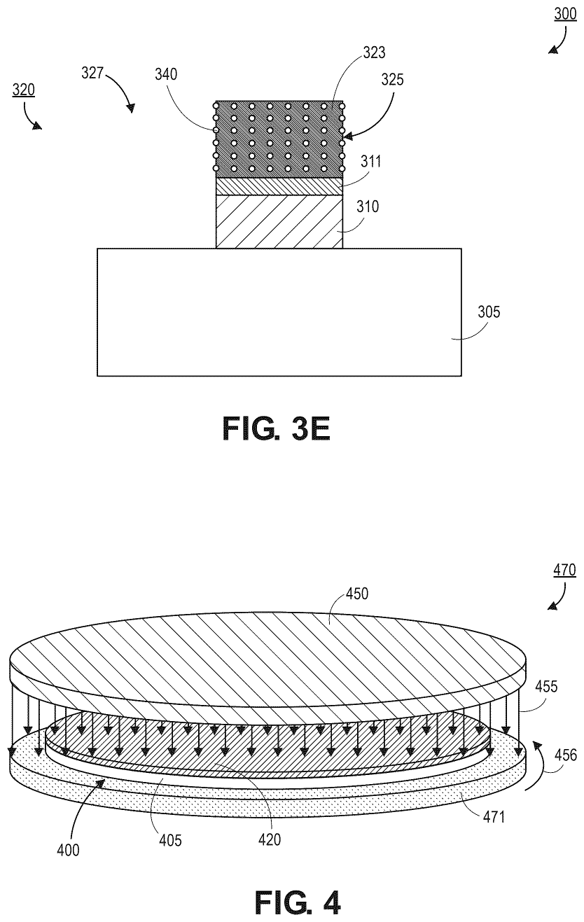

Referring now to FIG. 3A-3E, a series of cross-sectional illustrations depicting a process for developing an MOR material over a substrate after the MOR material is exposed to a magnetic field is shown, in accordance with an embodiment. In the embodiments illustrated with respect to FIG. 3A-3E, the resist layer 320 is depicted as a negative tone resist. Though, it is to be appreciated that similar principles for controlling the diffusion of metal radicals may be applied to positive tone resist systems as well.

Referring now to FIG. 3A, a cross-sectional illustration of a portion of a device 300 is shown, in accordance with an embodiment. In an embodiment, the device 300 may include a patterning stack 310 and a resist layer 320 over the patterning stack 310. The resist layer 320 and the patterning stack 310 may be provided over a substrate 305. In an embodiment, the substrate 305 may comprise a semiconductor substrate (e.g., a silicon wafer or the like), or any other layer of semiconductor manufacturing (e.g., a metal layer, a dielectric layer, and/or the like) that is desired to be patterned.

In an embodiment, the patterning stack 310 may include one or more layers suitable for transferring a pattern formed into the resist layer 320 into the underlying substrate 305. For example, the patterning stack 310 may comprise multiple layers, such as a silicon hardmask layer, a carbon hardmask layer, an antireflective coating, and/or the like. In some embodiments, the patterning stack 310 may comprise an underlayer 311. In an embodiment, the underlayer 311 may comprise a material that is sensitive to EUV radiation or DUV radiation in order to generate species (e.g., elements, molecules, electrons, etc.) that can diffuse into the overlying resist layer 320 in order to participate in the solubility switch reaction. In an embodiment, the underlayer 311 may be deposited with a dry deposition process (e.g., CVD, ALD, or the like). Though, in other embodiments the underlayer 311 may be omitted.

In an embodiment, the resist layer 320 may comprise a material that reacts when exposed to EUV and/or DUV radiation in order to generate a solubility switch. In a particular embodiment, the resist layer 320 may comprise an MOR material. The resist material may also include an organometallic oxide material. In an embodiment, an MOR material may comprise a photoresist material with one or more metals (e.g., tin, indium, hafnium, zinc, zirconium, tellurium, or any combination thereof). The MOR material may also comprise an organotin-oxo photoresist material, an organoindium-oxo photoresist material, or the like. In an embodiment, the resist layer 320 may be deposited over the underlying layers with any suitable process, such as a spin coating process or a dry deposition process (e.g., CVD, ALD, etc.).

As shown in FIG. 3A, the resist layer 320 is being exposed to radiation 309, such as DUV and/or EUV radiation. In an embodiment, a mask 308 or the like may be used to block radiation 309 (e.g., EUV radiation and/or DUV radiation). In an embodiment, the selective exposure of the resist layer 320 may result in the formation of an exposed region 323 and an unexposed region 321. In an embodiment, the radiation 309 may result in a chemical reaction within the exposed region 323 that drives the formation of reactive species and/or metal radicals. For example, metal radicals 340 are shown as being generated in FIG. 3A. In an embodiment, the metal radicals 340 are substantially randomly distributed about the exposed region 323. In some embodiments, the reactive species (not shown) may also be randomly distributed about the exposed region 323.

Referring now to FIG. 3B, a cross-sectional illustration of the portion of the device 300 while the resist layer 320 is exposed to a magnetic field 355 is shown, in accordance with an embodiment. In an embodiment, the device 300 may be brought into the magnetic field 355 in order to align the metal radicals 340 (and any other magnetically responsive species). In some instances, the magnetic field 355 may be generated by a magnetic structure 350 (e.g., comprising one or more permanent magnets, one or more electromagnets, and/or the like). In an embodiment, the magnetic field 355 may have any suitable strength. For example, the magnetic field 355 may be up to approximately 10.0 Teslas. Other embodiments may include a magnetic field 355 that is between approximately 1.0 Teslas and approximately 10.0 Teslas. Though, stronger or weaker magnetic fields 355 may be used in other embodiments.

In some embodiments, the magnetic field 355 may have magnetic field lines that are substantially orthogonal to the top surface of the resist layer 320. As such, the magnetic field lines may pass in a substantially vertical direction through a thickness of the resist layer 320. Though, in other embodiments, the magnetic field lines may be oriented to the top surface of the resist layer 320 at an angle between approximately 0° and approximately 90°. In such an embodiment, the metal radicals 340 (and any other reactive species that are responsive to the magnetic field 355) may align in substantially vertical lines through the resist layer 320. For example, the randomly distributed metal radicals 340 in FIG. 3A are redistributed into substantially ordered and aligned lines of magnetic radicals 340.

In an embodiment, the magnetic field 355 may restrict the uncontrolled diffusion of the metal radicals 340 and/or other reactive species after the radiation exposure process. In some embodiments, the magnetic field 355 may be applied during the radiation exposure and/or after the radiation exposure (e.g., within several seconds of the radiation exposure, within several minutes of the radiation exposure, or within an hour of the radiation exposure). In an embodiment, the magnetic field 355 may be applied to the resist layer 320 during the PEB process. In some embodiments, the magnetic field 355 may be applied during both the radiation exposure and during the PEB process. Accordingly, the elevated temperatures of the PEB process may not result in significant diffusion of the metal radicals 340 since they are held in place by the magnetic field. This may result in an improvement of the LER and/or LWR of the pattern formed in the resist layer 320 after development.

In some embodiments, the device 300 may be substantially stationary during the application of the magnetic field 355 to the resist layer 320. Though, in other embodiments, the resist layer 320 may be rotated through the magnetic field 355 (or the magnetic field 355 may be rotated relative to the resist layer 320). The rotation of the resist layer 320 (and/or the magnetic field 355) may provide some improvements for process uniformity. An example of a rotating system is provided in greater detail below with respect to FIG. 4.

Referring now to FIG. 3C, a cross-sectional illustration of the portion of the device 300 is shown, in accordance with an embodiment. As shown, the device 300 has been removed from the magnetic field 355. However, the positioning of the metal radicals 340 within the exposed region 323 may be substantially fixed since the temperature of the resist layer 320 is reduced after the PEB process. As shown, the substantially linear alignment of the metal radicals 340 provides a sharper interface that is more linear between the exposed region 323 and the unexposed region 321 of the resist layer 320 than is provided in a resist layer after a PEB process without a magnetic field, such as what is shown in FIG. 1C above.

Referring now to FIG. 3D, a cross-sectional illustration of the device 300 after the resist layer 320 is developed is shown, in accordance with an embodiment. In the illustrated embodiment, the resist layer 320 is shown as being a negative tone resist where the unexposed region 321 has been removed, and the exposed regions 323 remain behind. However, in other embodiments, the unexposed region 321 may remain, and the exposed regions 323 may be removed. In the case of a negative tone resist layer 320, the exposed regions 323 may be cross-linked during the PEB process through a condensation reaction that drives oxygen bonding between hydroxyl terminations of metal-oxide clusters in the exposed regions 323. The cross-linking of the metal-oxide clusters may improve the etch resistance in subsequent developing process.

Though, whether the resist layer 320 is a positive tone resist or a negative tone resist, the resulting sidewalls 325 of the openings 327 that are formed through the resist layer 320 may have improved flatness. That is, the sidewalls 325 may be substantially linear and provide improved LER and/or LWR compared to solutions that do not include exposing the resist layer to a magnetic field. In the case of a positive tone resist, the exposed regions 323 may be removed with the developing process, which may leave the sidewalls 325 along the unexposed regions 321.

Referring now to FIG. 3E, a cross-sectional illustration of the portion of the device 300 after the pattern of the opening 327 formed through the resist layer 320 is transferred into underlying layers (e.g., the underlayer 311 and the patterning stack 310) is shown, in accordance with an embodiment. In an embodiment, one or more etching processes may be used to etch through any number of the underlying layers while using the remaining portions of the resist layer 320 as a patterning mask. In an embodiment, the substantially linear sidewalls 325 of the opening 327 in the resist layer 320 may be maintained in the opening 327 as it continues through the underlying layers. As such, the pattern transfer may also retain the optimized LER and/or LWR patterning outcomes.

Referring now to FIG. 4, a perspective schematic illustration of a system 470 for exposing a device 400 with a resist layer 420 to a magnetic field 455 is shown, in accordance with an embodiment. In an embodiment, the system 470 may include a support 471 that retains the device 400. For example, the substrate 405 may be secured to the support 471. In an embodiment, the support 471 may comprise a heating element in order to implement a PEB process. Though, in other embodiments, the PEB heating may be implemented through heating sources external to the support 471. For example, the system 470 may be maintained in a heated environment (e.g., an oven or the like).

In an embodiment, a magnetic structure 450 may be provided over the device 400. The magnetic structure 450 may comprise a permanent magnet, an electromagnet, or the like. In some embodiments, the magnetic structure 450 may be configured to emit a magnetic field 455 with field lines (as indicated by the arrows) that are substantially orthogonal to a top surface of the resist layer 420. Though, in other embodiments, the magnetic field lines may be oriented to the top surface of the resist layer 420 at an angle between approximately 0° and approximately 90°. In some embodiments, the support 471 may be rotatable (as indicated by arrow 456) so that the resist layer 420 is rotated through the magnetic field 455. In other embodiments, the magnetic structure 450 may be rotatable so that the magnetic field 455 rotates about the resist layer 420.

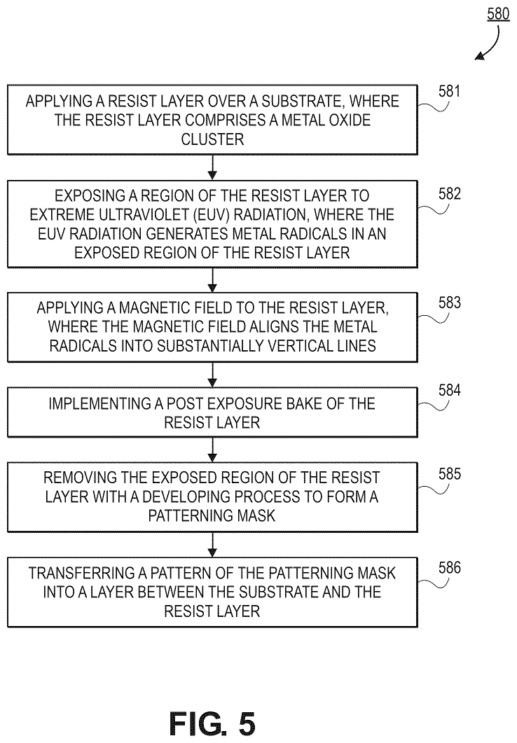

Referring now to FIG. 5, a process flow diagram that depicts a process 580 for developing a resist layer with the use of a magnetic field is shown, in accordance with an embodiment. In an embodiment, the process 580 may be similar to any of the processes described in greater detail herein. For example, the process 580 may comprises processing operations and/or conditions similar to any of those described with respect to FIG. 3A-3E.

In an embodiment, the process 580 may begin with operation 581, which comprises applying a resist layer over a substrate. In an embodiment, the resist layer may comprise a metal oxide cluster. For example, the resist layer may be an MOR material, such as any of the MOR materials described in greater detail herein. In a particular embodiment, the MOR material may comprise tin-oxide clusters.

In an embodiment, the process 580 may continue with operation 582, which comprises exposing a region of the resist layer to EUV radiation and/or DUV radiation. In an embodiment, the exposure results in the formation of metal radicals within the exposed region of the resist layer. In the case of a tin-oxide MOR material, the tin-oxide clusters lead to the formation of tin radicals. In an embodiment, the metal radicals may have one or more unpaired electrons that result in the metal radicals being responsive to magnetic fields.

In an embodiment, the process 580 may continue with operation 583, which comprises a magnetic field to the resist layer. In an embodiment, the magnetic field may align the metal radicals into substantially vertical lines. The magnetic field may also reduce the diffusion of the metal radicals (and/or any other magnetically responsive reactive species) within the exposed region of the resist layer. In an embodiment, the magnetic field may have a strength up to approximately 10.0 Teslas. In an embodiment, the resist layer may be rotated through the magnetic field, or the resist layer may remain stationary during the exposure to the magnetic field.

In an embodiment, the process 580 may continue with operation 584, which comprises implementing a PEB of the resist layer. In an embodiment, the PEB may result in the formation of a solubility switch in the exposed region. In some embodiments, the PEB process of operation 584 may be implemented during operation 583. That is, the PEB process may be implemented while the resist layer is exposed to the magnetic field. In other embodiments, the magnetic field may also be applied during the EUV exposure process of operation 582.

As can be appreciated, applying the magnetic field to the resist layer during the PEB process limits the uncontrolled diffusion that would otherwise occur at the elevated temperatures of the PEB process. Accordingly, the interface between the exposed regions and the unexposed regions of the resist layer remain well defined and more linear. This provides improved LER and/or LWR properties during resist development and subsequent pattern transfer operations.

In an embodiment, the process 580 may continue with operation 585, which comprises removing the exposed region of the resist layer (or the unexposed region, depending on the tone of the resist layer) with a developing process to form a patterning mask. In an embodiment, the patterning mask may have openings through the resist layer that are substantially vertical with lower LER and/or LWR compared to solutions that do not use magnetic fields to align metal radicals.

In an embodiment, the process 580 may continue with operation 586, which comprises transferring the pattern of the patterning mask into a layer between the substrate and the resist layer. For example, a patterning stack with a hardmask layer and/or the like may be patterned by one or more etching processes through the use of the resist layer as a patterning mask.

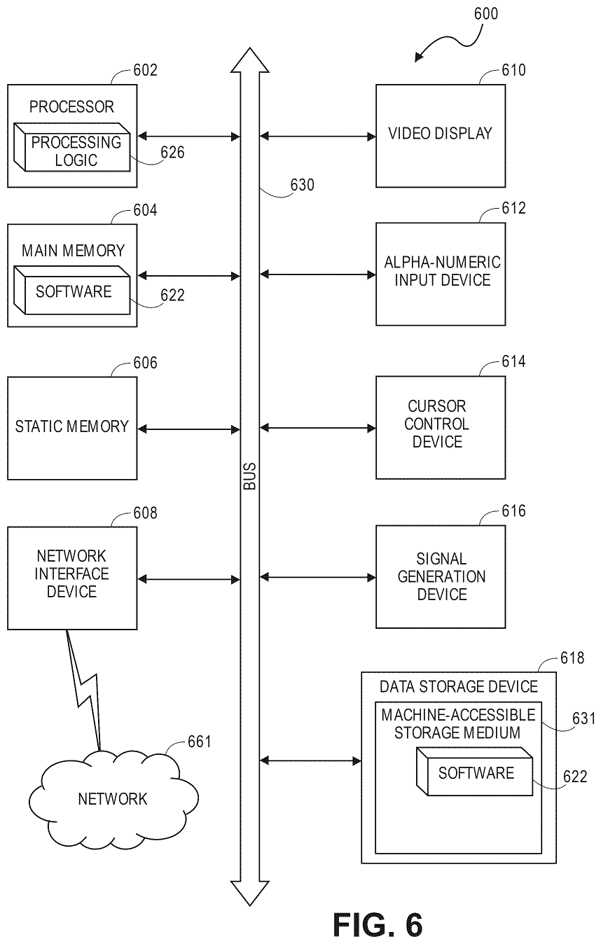

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 631 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 661 via the system network interface device 608. In an embodiment, the network interface device 608 may operate using RF coupling, optical coupling, acoustic coupling, or inductive coupling.

While the machine-accessible storage medium 631 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A method for developing a resist layer that has been exposed to form an exposed region with metal radicals, comprising:
applying a magnetic field to the resist layer, wherein the magnetic field aligns the metal radicals within the exposed region into substantially vertical lines;
implementing a post exposure bake of the resist layer; and
removing the exposed region of the resist layer or an unexposed region of the resist layer with a developing process to form a patterning mask.

2. The method of claim 1, wherein the resist layer comprises a metal oxide resist (MOR).

3. The method of claim 2, wherein the MOR comprises metal-oxide clusters, and wherein the metal-oxide clusters comprise one or more of tin, indium, hafnium, zinc, zirconium, or tellurium.

4. The method of claim 1, wherein the resist layer is exposed with extreme ultraviolet (EUV) radiation.

5. The method of claim 1, wherein the post exposure bake and applying the magnetic field to the resist layer are implemented at the same time.

6. The method of claim 1, wherein the magnetic field is applied to the resist layer during an exposure of the resist layer to form the exposed region.

7. The method of claim 1, wherein the magnetic field is applied to the resist layer after an exposure of the resist layer to form the exposed region.

8. The method of claim 1, wherein the magnetic field is applied to the resist layer during an exposure of the resist layer to form the exposed region and during the post exposure bake.

9. The method of claim 1, wherein magnetic field lines of the magnetic field applied to the resist layer are oriented at an angle between 0° and 90° with respect to a surface of the resist layer.

10. The method of claim 1, further comprising:
rotating the resist layer through the magnetic field.

11. The method of claim 1, further comprising:
transferring a pattern of the patterning mask into a layer under the resist layer.

12. The method of claim 1, wherein the magnetic field has a strength that is between approximately 1.0 Teslas and approximately 10.0 Teslas.

13. A method for developing a resist layer, comprising:
exposing a region of the resist layer to extreme ultraviolet (EUV) radiation, wherein the EUV radiation generates metal radicals in an exposed region of the resist layer;
exposing the resist layer to a magnetic field, wherein magnetic field lines of the magnetic field are oriented at an angle between 0° and 90° with respect to a surface of the resist layer, and wherein the magnetic field aligns the metal radicals within the exposed region;
implementing a post exposure bake of the resist layer; and
removing the exposed region of the resist layer or an unexposed region of the resist layer with a developing process to form a patterning mask.

14. The method of claim 13, wherein the resist layer comprises a metal-oxide resist (MOR) material.

15. The method of claim 14, wherein the MOR material comprises tin-oxide clusters, and wherein the metal radicals comprise tin radicals.

16. The method of claim 13, wherein the post exposure bake and applying the magnetic field to the resist layer are implemented at the same time.

17. The method of claim 13, wherein the magnetic field is applied to the resist layer during the EUV radiation exposure of the resist layer.

18. A method, comprising:
applying a resist layer over a substrate, wherein the resist layer comprises a metal oxide cluster;
exposing a region of the resist layer to deep ultraviolet (DUV) radiation and/or extreme ultraviolet (EUV) radiation, wherein the DUV radiation and/or EUV radiation generates metal radicals from the metal oxide cluster in an exposed region of the resist layer;
exposing the resist layer to a magnetic field, and wherein the magnetic field aligns the metal radicals within the exposed region;
implementing a post exposure bake of the resist layer; and
removing the exposed region of the resist layer or an unexposed region of the resist layer with a developing process to form a patterning mask.

19. The method of claim 18, wherein the resist layer is exposed to the magnetic field during the post exposure bake.

20. The method of claim 18, further comprising:
rotating the resist layer through the magnetic field.
